(19) United States
(12) Patent Application Publication
(10) Pub. No.: US 2012/0292092 A1
(43) Pub. Date: Nov. 22, 2012

(54) METHOD OF MANUFACTURING CIRCUIT BOARD AND CIRCUIT BOARD MANUFACTURED BY THE METHOD

(75) Inventors: Sang-min LEE, Changwon-city (KR); Soon-chul KWON, Changwon-city (KR)

(73) Assignee: SAMSUNG TECHWIN CO., LTD., Changwon-city (KR)

(21) Appl. No.: 13/343,347

(22) Filed: Jan. 4, 2012

(30) Foreign Application Priority Data
May 19, 2011 (KR) 10-2011-0047469
Aug. 30, 2011 (KR) 10-2011-0087197

(51) Int. Cl. H05K 1/11; C03C 15/00; H05K 3/00

(52) U.S. Cl. 174/266; 156/252; 216/17

(57) ABSTRACT

A method of manufacturing a circuit board includes: providing a base substrate that comprises a first electrically conductive layer that has an inner circuit pattern formed on at least one surface of the base substrate; attaching a build-up material to the base substrate to insulate the first electrically conductive layer from outside; forming one or more holes at one time in the build-up material attached to the base substrate; forming a stack by curing the build-up material in which the one or more holes are formed; and forming a second electrically conductive layer that has an outer circuit pattern formed on at least one outer surface of the stack. The method may form the holes without drilling.

### CROSS-REFERENCE TO RELATED PATENT APPLICATIONS

This application claims priority from Korean Patent Application No. 10-2011-0047469 filed on May 19, 2011, and Korean Patent Application No. 10-2011-0087197 filed on Aug. 30, 2011, in the Korean Intellectual Property Office, the disclosures of which are incorporated herein in their entirety by reference.

### BACKGROUND

1. Field

Methods and apparatuses consistent with exemplary embodiments relate to a circuit board, and more particularly, to a circuit board in which holes may be formed without drilling.

2. Description of the Related Art

Recently, as components of electronic devices become smaller in size and consumers prefer a product having various functions, the number of components comprising an electronic device has increased. Accordingly, there is a demand for technology for mounting more electronic components on a circuit board at a higher density.

A multi-layer circuit board is an element of an electronic device which includes a plurality of substrates stacked as a plurality of layers and electronic components that are mounted on the stacked substrates. Since a multi-layer circuit board may perform more functions than a single or double-sided circuit board and allows electronic components to be mounted thereon at a higher density, the multi-layer circuit board is widely used in various electronic devices.

A multi-layer circuit board is manufactured by forming a wiring for electrically connecting components to substrates that are formed as a plurality of layers, stacking the substrates, forming holes for electrically connecting the layers, and plating the holes or filling conductive paste in the holes.

Drilling to form holes is very cumbersome and requires many processes, thereby increasing manufacturing costs. As semiconductors have more functions and the number of input and output signals have increased to make a circuit more complex, the number of holes for connecting circuits needs to be increased and the size of the holes needs to be reduced, thereby greatly increasing time and costs for forming the holes.

### SUMMARY

One or more exemplary embodiments provide a method of manufacturing a circuit board with a simplified process and reduced costs and a circuit board manufactured by the method.

According to an aspect of an exemplary embodiment, there is provided a method of manufacturing a circuit board, the method including: providing a base substrate that comprises a first electrically conductive layer that has an inner circuit pattern formed on at least one surface of the base substrate; attaching a build-up material to the base substrate to insulate the first electrically conductive layer from outside; forming one or more holes at one time in the build-up material attached to the base substrate; forming a stack by curing the build-up material in which the one or more holes are formed; and forming a second electrically conductive layer that has an outer circuit pattern formed on at least one outer surface of the stack.

The build-up material may include a reinforcing material and a matrix material mixed with the reinforcing material.

The reinforcing material may include at least one of a glass fabric and a silica-based filler, and the matrix material may include pre-cured epoxy.

The forming the stack may include cross-linking pre-cured epoxies together.

A process temperature when the build-up material is cured may be higher than a process temperature when the build-up material is attached to the base substrate.

The forming the one or more holes may include forming the one or more holes by using wet etching that removes portions of the build-up material where the one or holes are to be formed by using a solution.

The solution may be a glass etching agent.

The forming the one or more holes may include: removing the matrix material included in the build-up material at the portions where the one or more holes are to be formed by using a first solution; and removing the reinforcing material included in the build-up material at the portions where the one or more holes are to be formed by using a second solution.

A metal layers may be formed on the at least one outer surface of the build-up material.

The method may further include removing the metal layer in the portions where the one or more holes are to be formed, before the forming the one or more holes.

The second electrically conductive layer on which the outer circuit pattern is formed may be formed by using tenting, a modified semi-additive process (MSAP) or a semi-additive process (SAP).

The method may further include, after the forming the stack, filling conductive paste in the one or more holes or plating inner walls of the one or more holes with a metal material so that the first electrically conductive layer is connected to the second electrically conductive layer.

According to an aspect of another exemplary embodiment, there is provided a method of manufacturing a circuit board, the method including: preparing a build-up material having both surfaces to which electrically conductive layers are attached; forming one or more openings in the electrically conductive layers so that the build-up material is exposed; forming one or more holes corresponding to the one or more openings in the build-up material at one time; forming a stack by curing the build-up material in which the one or more holes are formed; and forming circuit patterns on both surfaces of the stack.

The build-up material may include a reinforcing material and a matrix material mixed with the reinforcing material.

The reinforcing material may include at least one of a glass fabric and a silica-based filler, and the matrix material may include pre-cured epoxy.

The forming the stack may include cross-linking pre-cured epoxies together.

A process temperature when the build-up material is cured may be higher than a process temperature when the electrically conductive layers are attached to the build-up material.

The forming the one or more holes may include forming the one or more holes by using wet etching that removes portions of the build-up material where the one or more holes are to be formed by using a solution.

The solution may include a glass etching agent.

The forming the one or more holes may include: removing the matrix material included in the build-up material at the portions where the one or more holes are to be formed by using a first solution; and removing the reinforcing material included in the build-up material at the portions where the one or more holes are to be formed by using a second solution.

According to an aspect of another exemplary embodiment, there is provided a circuit board manufactured by the above method.

### BRIEF DESCRIPTION OF THE DRAWINGS

The above and other aspects will become more apparent by describing in detail exemplary embodiments with reference to the attached drawings, in which:

FIGS. 1, 2, 4 through 7, and 9 are cross-sectional views illustrating a method of manufacturing a circuit board, according to an exemplary embodiment;

FIG. 3 is an enlarged view illustrating a build-up material of the circuit board of FIG. 2, according to an exemplary embodiment;

FIG. 8 is a graph illustrating a relationship between a process temperature and time of the method of FIGS. 1, 2, 4 through 7, and 9, according to an exemplary embodiment; and

FIGS. 10 through 14 are cross-sectional views illustrating a method of manufacturing a circuit board, according to another exemplary embodiment.

### DETAILED DESCRIPTION OF THE EXEMPLARY EMBODIMENTS

As the inventive concept allows for various changes and numerous embodiments, exemplary embodiments will be illustrated in the drawings and described in detail in the written description. However, this is not intended to limit the inventive concept to particular modes of practice, and it is to be appreciated that all changes, equivalents, and substitutes that do not depart from the spirit and technical scope of the inventive concept are encompassed by the present application. In the description of the exemplary embodiments, certain detailed explanations of related art are omitted when it is deemed that they may unnecessarily obscure the essence of the inventive concept.

The terms “first,” “second,” and the like, “primary,” “secondary,” and the like, as used herein do not denote any order, quantity, or importance, but rather are used to distinguish one element, region, component, layer, or section from another.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” used herein specify the presence of stated features, integers, steps, operations, members, components, and/or groups thereof, but do not preclude the presence or addition of one or more other features, integers, steps, operations, members, components, and/or groups thereof.

The exemplary embodiments will now be described more fully with reference to the accompanying drawings.

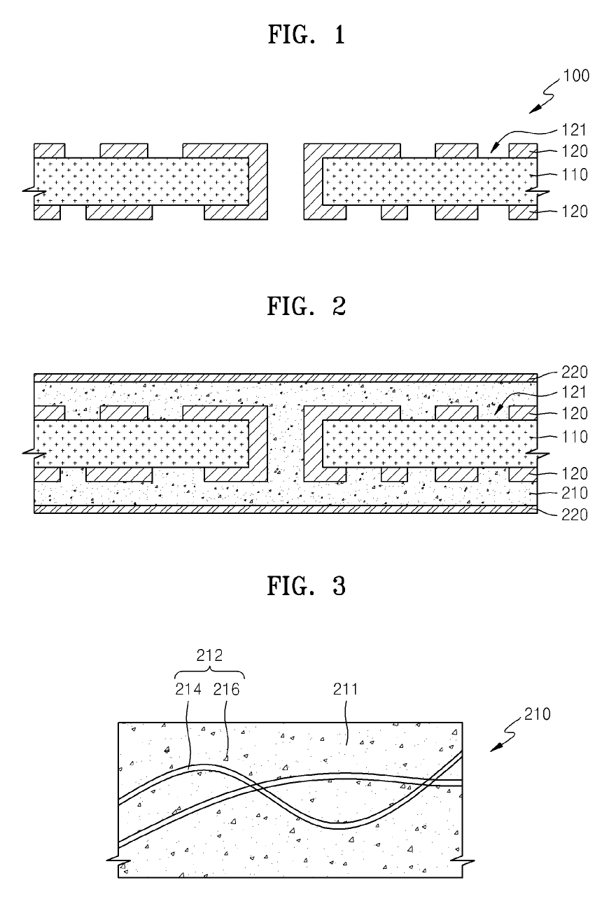

FIGS. 1, 2, 4 through 7, and 9 are cross-sectional views illustrating a method of manufacturing a circuit board, according to an exemplary embodiment. FIG. 3 is an enlarged view illustrating a build-up material of the circuit board of FIG. 2, according to an exemplary embodiment. FIG. 8 is a graph illustrating a relationship between a process temperature and time of the method of FIGS. 1, 2, 4 through 7, and 9, according to an exemplary embodiment.

Referring to FIG. 1, a base substrate 100 is prepared.

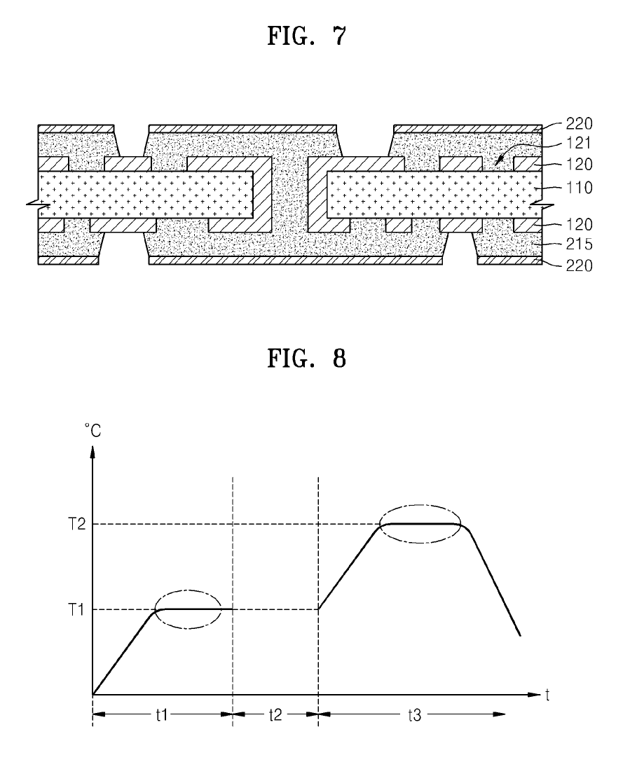

The base substrate 100 includes inner circuit patterns 121 for transmitting an electrical signal. Specifically, the base substrate 100 includes electrically conductive layers 120 that have the inner circuit patterns 121 formed on both surfaces of a core substrate 110. The core substrate 110 may include the same material as that of a stack 215 (see FIG. 7) as explained below, but the present embodiment is not limited thereto. The electrically conductive layers 120 may include an electrically conductive material such as copper (Cu) or silver (Ag), but the present embodiment is not limited thereto. The electrically conductive layers 120 may be formed on both surfaces of the core substrate 110 by using screen printing or roll coating. The inner circuit patterns 121 may be formed by using any of various patterning methods such as tenting, a modified semi-additive process (MSAP), and a semi-additive process (SAP).

Although not shown, holes may be formed in the base substrate 100 to manufacture a multi-layer circuit board. A thickness, a material, a shape, a configuration, and so on of the base substrate 100 are not limited to those described above, and may vary according to need.

Referring to FIG. 2, a build-up material 210 is attached to the base substrate 100.

Here, the attachment refers to a process of filling the build-up material 210 in and around the inner circuit patterns 121 to cover the inner circuit patterns 121 of the base substrate 100 without curing the build-up material 210. The attachment of FIG. 2 may be performed at a predetermined pressure and a predetermined temperature such that the build-up material 210 that has predetermined fluidity is sufficiently filled in and around the inner circuit patterns 121.

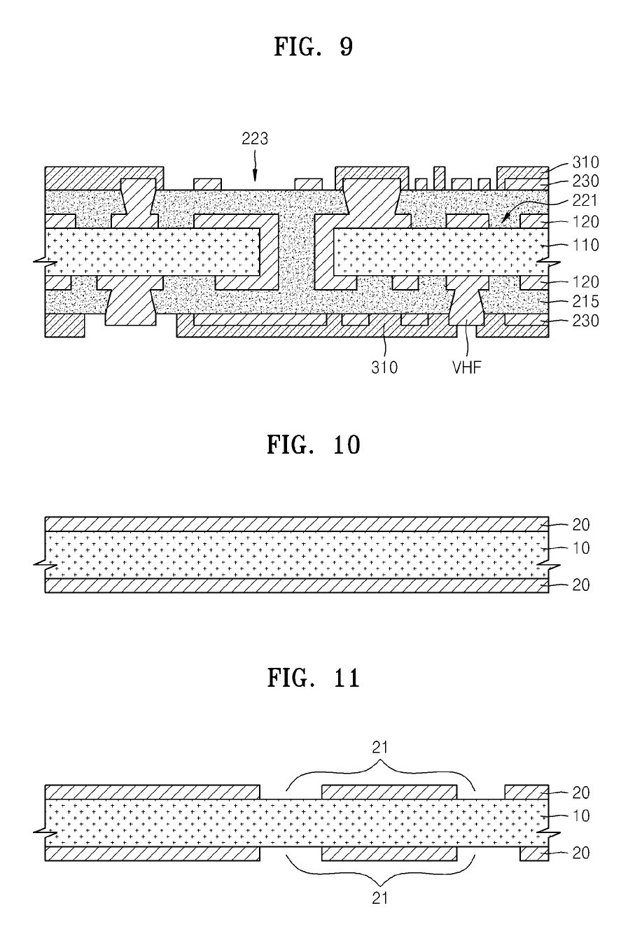

The build-up material 210 insulates the inner circuit patterns 121 and outer circuit patterns 223 (see FIG. 9) when a multi-layer circuit board is manufactured, and includes a reinforcing material 212 (see FIG. 3) and a matrix material 211 (see FIG. 3) mixed in the reinforcing material 212.

FIG. 3 is an enlarged view illustrating the build-up material 210 of the circuit board of FIG. 2.

The reinforcing material 212 is a material added to increase the mechanical and chemical strength and durability of the stack 215 (see FIG. 7). For example, the reinforcing material 212 may include at least one of the glass fabric 214 and the filler 216, for example, a silica-based filler, but the present embodiment is not limited thereto. The glass fabric 214 is weaved as a linear material in the stack 215 (see FIG. 7) or the build-up material 210 to support the stack 215 (see FIG. 7), like an iron bar in a piece of ferroconcrete. The filler 216 is dispersed as particles in the stack 215 (see FIG. 7) or the build-up material 210 to increase the strength and durability of the stack 215 (see FIG. 7) or the build-up material 210, like gravel in a piece of ferroconcrete.

The matrix material 211 may take various forms according to whether curing occurs, be mixed with the reinforcing material 212, and insulate different electrically conductive layers. In an attachment step, the matrix material 211 includes a semi-cured polymer material or a pre-cured polymer material. For example, the matrix material 211 may include pre-cured epoxy. Accordingly, in the attachment step, the build-up material 210 has predetermined fluidity and has low chemical resistance and low durability. In a curing step, as explained below, the stack 215 (see FIG. 7) is obtained by thermally curing pre-cured epoxy to remove fluidity, increase chemical resistance, and increase the strength and durability of the stack 215 (see FIG. 7).

As shown in FIG. 2, metal layers 220 may be respectively formed on outer surfaces of the build-up material 210 facing the base substrate 100. The metal layers 220 may be formed of a material such as Cu or Ag, and may have a thickness less than a thickness of the electrically conductive layers 120 illustrated in FIG. 1. However, the present embodiment is not limited thereto, and the build-up material 210 on which the metal layers 220 are not formed may be coated on the base substrate 100.

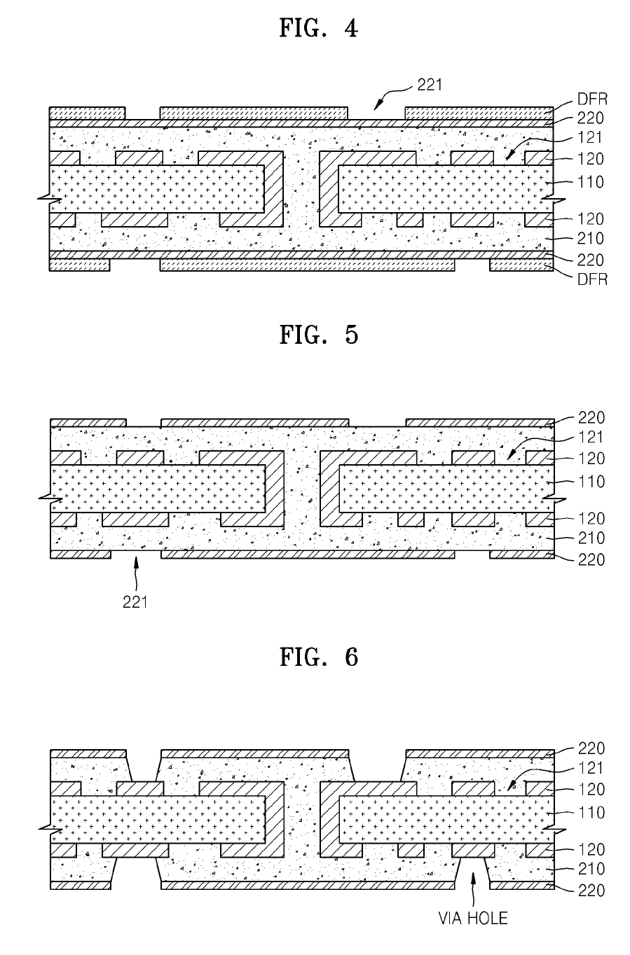

Referring to FIGS. 4 and 5, portions 221 of the metal layers 220 where via holes are to be formed are removed.

In detail, a process of FIGS. 4 and 5 is called a window process. Since the via holes in the build-up material 210 are not formed by using drilling but are formed by using wet etching, if the metal layers 220 are formed on the build-up material 210, the window process is performed. Referring to FIG. 4, a dry film resist (DRF) is coated on the metal layers 220, exposure and development are performed, and patterns are formed at the portions where the via holes are to be formed. Referring to FIG. 5, the portions 221 of the metal layers 220 where the via holes are to be formed are removed by using the DFR as a mask, and then, the DFR is removed by using stripping. The window process may be performed in a way other than that illustrated in FIGS. 4 and 5.

Referring to FIG. 6, one or more via holes may be formed at one time in the build-up material 210 of FIG. 5.

In detail, the via holes are formed by using wet etching that removes portions of the build-up material 210 at the portions 221 where the via holes are to be formed by using a solution. Since the solution has to be capable of removing the reinforcing material 212 as well as the matrix material 211 of the build-up material 210, the solution includes a glass etching agent that may remove the reinforcing material 212 formed of glass. The portions of the build-up material 210 may be removed in one process or in a plurality of processes. For example, the matrix material 211 included in the build-up material 210 at the portions where the via holes are to be formed may be removed by using a first solution that removes the matrix material 211 in a first step, and then, the reinforcing material 212 included in the build-up material 210 at the portions 221 where the via holes are to be formed may be removed by using a second solution that removes the reinforcing material 212 in a second step. Of course, if desired, the first step may be repeatedly performed after the second step. The first solution may be a basic solution such as sodium permanganate or sodium hydroxide, an organic solvent such as acetone, or other acidic solution. Also, an acidic, basic, or neutral etching assistant chemical may be used before the etching. The second solution may be an acidic solution such as hydrofluoric (HF) acid, or a well-known glass etching agent.

According to the present embodiment, the via holes are formed in a state where the build-up material 210 is attached. Since chemical resistance is low when the build-up material 210 is attached without being cured, the via holes may be sufficiently formed by using wet etching. However, if the build-up material 210 is cured immediately after the build-up material 210 is formed on the base substrate 100 as in a related art method, since the build-up material 210 is already cured and is changed to the stack 215 (see FIG. 7) having high chemical resistance, it is impossible to form the Via holes by using wet etching.

According to the present embodiment, since the via holes are formed by using wet etching, first, the via holes do not need to be individually formed as in the related art drilling, and instead, tens, hundreds, or thousands of via holes may be formed in one process. Drilling takes long and incurs high costs in a method of manufacturing a circuit board and requires high equipment costs. Accordingly, according to the present embodiment, manufacturing time and costs may be reduced. Second, throughput is improved compared to the related art drilling. Third, smears, which are generated in the related art drilling, are not generated. Also, since expensive drilling equipment is not required, manufacturing costs may be reduced considerably.

Referring to FIG. 7, the stack 215 is formed by curing the build-up material 210 in which the via holes are formed.

In detail, curing refers to a process of forming the stack 215 by thermally curing the matrix material 211 in a semi-cured state or a pre-cured state which is included in the build-up material 210 to increase the chemical resistance, strength, durability of the stack 215, and so on. That is, since pre-cured epoxies are cross-linked together in the curing, the stack 215 includes cured epoxy having a network structure in which the reinforcing material 212 is mixed. Since the matrix material 211 is heat-curable, the matrix material 211 may be cured at high temperature. It is preferable that a temperature of the curing is higher than a temperature of the attachment of FIG. 2.

FIG. 8 is a graph illustrating a relationship between a process temperature and time of the method of FIGS. 1, 2, 4 through 7, and 9.

The method includes the attachment and the curing. That is, a step of attaching the build-up material 210 at a temperature T1 is performed in a period t1, and a step of forming the via holes by using etching is performed in a period t2. After the via holes are formed by etching, a step of forming the stack 215 by curing the build-up material 210 at a temperature T2 is performed in a period t3. According to the present embodiment, the stack 215 of the circuit board may include a polymer material having high strength and high durability, and have properties appropriate for packaging, and the via holes may be formed at one time by using wet etching through attachment and curing. Accordingly, the method of the present embodiment may be used to manufacture a circuit board having properties that satisfy requirements of users in a process with reduced lead time, investment costs, and equipment costs.

Referring to FIG. 9, electrically conductive layers 230 that have the outer circuit patterns 223 formed on outer surfaces of the cured stack 215 are formed, the via holes are processed, a protective layer 310 is printed, and surface treatment is performed, to complete the circuit board.

The outer circuit patterns 223 may be formed by using any of various patterning methods such as tenting, an MSAP, and an SAP. The outer circuit patterns 223 may be formed more finely than the inner circuit patterns 121. For example, if the outer circuit patterns 223 are formed by using pattern plating such as an MSAP, a mask is formed on the metal layers 220 (see FIG. 7) by using a DFR such that plating is performed on only desired patterns, plating is performed according to the desired patterns, and the DRF is removed by using stripping or flash etching. When the DFR is removed, the metal layers 220 located under the DRF may also be removed. When the outer circuit patterns 223 are formed as described above, the electrically conductive layers 230 including the outer circuit patterns 223 formed by using the pattern plating may be further formed on the metal layers 220 or on the stack 215 including no metal layers 220. However, the present embodiment is not limited thereto, and the outer circuit patterns 223 may be directly formed on the metal layers 220 that have a predetermined thickness.

Although conductive paste is filled in the via holes to form a via hole filler in FIG. 9, the present embodiment is not limited thereto and inner walls of the via holes may be plated by using a metal material. Accordingly, electric current may flow through the via holes.

The protective layer 310 may be formed of photo solder resist (PSR) and may include a component in which acrylate is included in exposable epoxy, but the present embodiment is not limited thereto.

Although the circuit board is a multi-layer circuit board including four (4) electrically conductive layers 120 and 220 in total in the above embodiment, the inventive concept is not limited thereto and a circuit board including various number of layers such as six (6) layers or eight (8) layers may be manufactured.

FIGS. 10 through 14 are cross-sectional views illustrating a method of manufacturing a circuit board, according to another exemplary embodiment.

Referring to FIGS. 10 through 14, a two-layer circuit board includes electrically conductive layers 20 which have circuit patterns 30 formed on both sides of a stack 15, unlike in the embodiments of FIGS. 1, 2, 4 through 7, and 9. A detailed explanation which will be made in FIGS. 10 through 14 may be a method of manufacturing the base substrate 100 of FIGS. 1, 2, 4 through 7, and 9.

Referring to FIG. 10, a build-up material 10 to both surfaces of which the electrically conductive layers 20 are attached is prepared.

The build-up material 10 insulates the electrically conductive layers 20 attached to both surfaces of the build-up material 10, like the build-up material 210 (see FIG. 2), and includes the reinforcing material 212 (see FIG. 3) and the matrix material 211 (see FIG. 3) mixed with the reinforcing material 212. The build-up material 10 is the same as the build-up material 210 of FIG. 2, and thus, a detailed explanation thereof will not be given.

The build-up material 10 has predetermined fluidity when the electrically conductive layers 20 are attached to the build-up material 10. The matrix material 211 (see FIG. 3) includes a semi-cured polymer material or a pre-cured polymer material. For example, the matrix material 211 (see FIG. 3) may include pre-cured epoxy. Accordingly, the build-up material 10 may have predetermined fluidity, and have low chemical resistance, low strength, and low durability. The reinforcing material 212 may include at least one of the glass fabric 214 (see FIG. 3) and the filler 216 (see FIG. 3), for example, a silica-based filler, but the present embodiment is not limited thereto.

The electrically conductive layers 20 of FIG. 10 may be formed of Cu and may be copper clad laminates, but the present embodiment is not limited thereto.

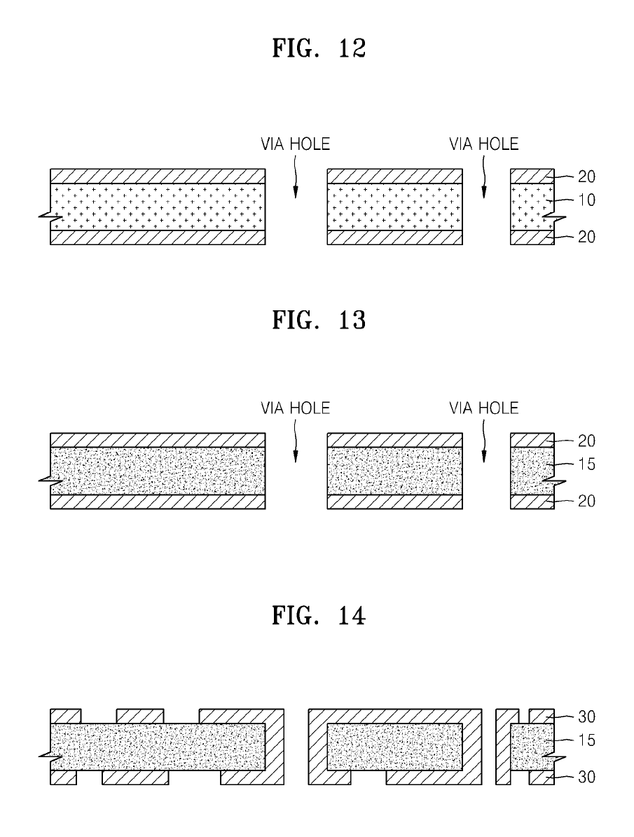

Referring to FIG. 11, a window process of removing portions of the electrically conductive layers 20 where via holes (see FIG. 12) are to be formed is performed, like in FIGS. 4 and 5.

The window process shown in FIG. 11 is a process for forming via holes (see FIG. 12) in the build-up material 10 by using etching, instead of drilling. The window process of FIG. 11 includes applying a DRF and forming patterns on portions where holes are to be formed through exposure and development, as described above with reference to FIGS. 4 and 5. Next, the window process includes forming openings 21 by removing (etching) the portions of the electrically conductive layers 20 where the holes are to be formed by using the DFR as a mask, and stripping the DFR.

Referring to FIG. 12, one or more via holes are formed at one time in the build-up material 10, like in FIG. 6.

The via holes are formed by using wet etching that removes portions of the build-up material 10 exposed through the openings 21 by using a solution. Since the solution has to be capable of removing the reinforcing material 212 (see FIG. 3) as well as the matrix material 211 (see FIG. 3), the solution includes a glass etching agent capable of removing the reinforcing material 212 (see FIG. 3) formed of glass. The portions of the build-up material 10 may be removed in one process or in a plurality of processes. For example, the matrix material 211 (see FIG. 3) included in the build-up material 10 may be removed by using a first solution for removing the matrix material 211 (see FIG. 3) in a first step, and the reinforcing material 212 (see FIG. 3) included in the build-up material 10 may be removed by using a second solution for removing the reinforcing material 212 (see FIG. 3) in a second step. The first step may be repeatedly performed after the second step, if desired.

Referring to FIG. 13, the stack 15 is formed by curing the build-up material 10 in which the via holes are formed, like in FIG. 7. By the time the stack 15 is formed by curing the build-up material 10, the build-up material has been in a state of attachment explained in the previous embodiment.

In detail, curing refers to a process of forming the stack 15 by thermally curing the matrix material 211 (see FIG. 3) in a semi-cured state or a pre-cured state which is included in the build-up material 10, to increase the chemical resistance, strength, and durability of the stack 15. That is, since pre-cured epoxies are cross-linked together in the curing, the stack 15 includes cured epoxy having a three-dimensional (network) structure in which a plurality of the reinforcing materials 212 (see FIG. 3) are mixed. Here, a temperature of the curing may be higher than a temperature of the attachment of FIG. 10.

Referring to FIG. 14, the circuit patterns 30 are formed on the electrically conductive layers 20, and the via holes are processed, to complete the two-layer circuit board, like in FIG. 9. The circuit patterns 30 may be formed by using any of various patterning methods such as tenting, an MSAP, and an SAP.

Although predetermined holes including via holes and plated through-holes, predetermined circuit patterns, and so on are illustrated in the above embodiments, for convenience of explanation, the inventive concept is not limited thereto and other shapes, other numbers, and other patterns may be included without departing from the scope of the inventive concept.

As described above, according to the above embodiments, a process of manufacturing a circuit board may be simplified, manufacturing costs may be reduced, and cost competitiveness may be increased.

While the inventive concept has been particularly shown and described with reference to exemplary embodiments thereof, it will be understood by one of ordinary skill in the art that various changes in form and details may be made therein without departing from the spirit and scope of the inventive concept as defined by the following claims.

1. A method of manufacturing a circuit board, the method comprising:
providing a base substrate that comprises a first electrically conductive layer that has an inner circuit pattern formed on at least one surface of the base substrate;
attaching a build-up material to the base substrate to insulate the first electrically conductive layer from outside;
forming one or more holes at one time in the build-up material attached to the base substrate;
forming a stack by curing the build-up material in which the one or more holes are formed; and
forming a second electrically conductive layer that has an outer circuit pattern formed on at least one outer surface of the stack.

2. The method of claim 1, wherein the build-up material comprises a reinforcing material and a matrix material mixed with the reinforcing material.

3. The method of claim 2, wherein the reinforcing material comprises at least one of a glass fabric and a silica-based filler, and the matrix material comprises pre-cured epoxy.

4. The method of claim 3, wherein the forming the stack comprises cross-linking pre-cured epoxies together.

5. The method of claim 1, wherein a process temperature when the build-up material is cured is higher than a process temperature when the build-up material is attached to the base substrate.

6. The method of claim 1, wherein the forming the one or more holes comprises forming the one or more holes by using wet etching that removes portions of the build-up material at portions where the one or holes are to be formed by using a solution.

7. The method of claim 6, wherein the solution is a glass etching agent.

8. The method of claim 6, wherein the forming the one or more holes comprises:
removing the matrix material included in the build-up material at the portions where the one or more holes are to be formed by using a first solution; and
removing the reinforcing material included in the build-up material at the portions where the one or more holes are to be formed by using a second solution.

9. The method of claim 1, wherein a metal layer is formed on the at least one outer surface of the stack.

10. The method of claim 9, further comprising removing the metal layer in the portions where the one or more holes are to be formed, before the forming the one or more holes.

11. The method of claim 1, wherein the second electrically conductive layer on which the outer circuit pattern is formed is formed by using tenting, a modified semi-additive process (MSAP) or a semi-additive process (SAP).

12. The method of claim 1, further comprising, after the forming the stack, filling conductive paste in the one or more holes or plating inner walls of the one or more holes with a metal material.

13. A method of manufacturing a circuit board, the method comprising:
preparing a build-up material that has both surfaces to which electrically conductive layers are attached;
forming one or more openings in the electrically conductive layers so that the build-up material is exposed;
forming one or more holes corresponding to the one or more openings in the build-up material at one time;
forming a stack by curing the build-up material in which the one or more holes are formed; and
forming circuit patterns on both surfaces of the stack.

14. The method of claim 13, wherein the build-up material comprises a reinforcing material and a matrix material mixed with the reinforcing material.

15. The method of claim 14, wherein the reinforcing material comprises at least one of a glass fabric and a silica-based filler, and the matrix material comprises pre-cured epoxy.

16. The method of claim 15, wherein the forming the stack comprises cross-linking pre-cured epoxies together.

17. The method of claim 13, wherein a process temperature when the build-up material is cured is higher than a process temperature when the electrically conductive layers are attached to the build-up material.

18. The method of claim 13, wherein the forming the one or more holes comprises forming the one or more holes by using wet etching that removes portions of the build-up material where the one or more holes are to be formed by using a solution.

19. The method of claim 18, wherein the solution comprises a glass etching agent.

20. The method of claim 18, wherein the forming the one or more holes comprises:
removing the matrix material included in the build-up material at the portions where the one or more holes are to be formed by using a first solution; and
removing the reinforcing material included in the build-up material at the portions where the one or more holes are to be formed by using a second solution.

21. A circuit board manufactured by the method of claim 1.

22. A circuit board manufactured by the method of claim 13.
